(19) United States
(12) Patent Application Publication
(10) Pub. No.: US 2004/0195963 A1
(43) Pub. Date: Oct. 7, 2004

(54) Organic electro-luminescent display device

(75) Inventors: Beohm-Rock Choi, Seoul (KR); Joon-Hoo Choi, Seoul (KR); Jae-Hoon Chung, Suwon-si (KR); Jin-Koo Chung, Suwon-si (KR); Dong-Won Lee, Seongnam-si (KR); Sang-Pil Lee, Seoul (KR)

Correspondence Address: Frank Chau, F. CHAU & ASSOCIATES, LLP, Suite 501, 1900 Hempstead Turnpike, East Meadow, NY, 11554, US

(73) Assignee: Samsung Electronics Co., Ltd.

(21) Appl. No.: 10/788,153

(22) Filed: Feb. 26, 2004

(30) Foreign Application Priority Data
Apr. 7, 2003 (KR) 2003-21644

(51) Int. Cl. H05B 33/14

(52) U.S. Cl. 313/504; 313/506

(57) ABSTRACT

A display device comprises a plurality of first electrodes formed on a substrate, a plurality of second electrodes formed on the substrate below the plurality of first electrodes, an organic luminescent layer formed between the plurality of first electrodes and the plurality of second electrodes, and a color filter layer formed on the substrate, wherein the color filter layer includes a red filter, a green filter, a blue filter and a white filter.

### BACKGROUND OF THE INVENTION

1. Technical Field

The present disclosure relates to an organic electro-luminescent display device, and more particularly to an organic electro-luminescent display device using a 4-color system for forming a color image.

2. Discussion of the Related Art

An organic electro-luminescent display (OELD) device such as an active matrix organic light emitting diode (AMOLED) may include an anode including a transparent electrode made from, for example, indium tin oxide (ITO), a cathode including a metal electrode having a low work function, and an organic luminescent layer including an organic thin layer interposed between the anode and cathode.

When a direct current is applied to the OELD device, a plurality of holes is emitted from the anode and injected into the organic luminescent layer, and a plurality of electrons is emitted from the cathode and injected into the organic luminescent layer. The holes and electrons are recombined in the organic luminescent layer to emit light. The OELD device structure is simple and light efficiency is high due to the self-emitting characteristics of the organic material in the organic luminescent layer.

Some structures for forming a full color image using an OELD device are known. For example, as shown in FIG. 1A, an independent red, green, blue (RGB) layer structure uses three organic luminescent layers 20, 22, and 24 independently coated on a substrate 10 for emitting red, green, and blue light, respectively. As shown in FIG. 1B, a color transformation structure uses color transformation layers 30, 32, and 34 interposed between the substrate 10 and a blue luminescent layer 36. As shown in FIG. 1C, a color filter structure uses color filters 40, 42, and 44 for emitting the red, green and blue light respectively. The color filters 40, 42, and 44 are interposed between the substrate 10 and a white organic luminescent layer 46.

When using the independent RGB layer structure shown in FIG. 1A, the RGB material is deposited and patterned using a shadow mask. As a result, although there is high light efficiency, the red, green and blue light cannot be minutely separated from each other. The color transformation structure shown in FIG. 1B requires that an organic fluorescent material is deposited on the substrate by an exposure process, thereby adding a process step for forming the full color image. In addition, when using the color transformation structure, it is difficult to coat the color transformation layer with a uniform thickness. When using the color filter structure shown in FIG. 1C, the color filter is formed through a conventional photolithography process. As a result, a relatively higher resolution display panel is manufactured using the color filter structure and the color filter structure is more widely used than the other structures.

However, the color filter structure requires a high efficiency white organic luminescent material because the light efficiency of the white light is reduced as the white light passes through the color filters after being emitted from the white organic luminescent layer 46. Accordingly, an operation efficiency of an OELD device using the color filter structure is lower than that of an OELD device using the independent RGB layer structure. Research has been conducted to find an organic luminescent material having a high luminance and a high efficiency enough to compensate for the light transmittance reduction which occurs with the color filter structure. However, such an organic luminescent material has not yet been found.

Therefore, there is a need for an OELD device having a structure that results in improved luminance and light efficiency.

### SUMMARY OF THE INVENTION

A display device, in accordance with an embodiment of the present invention, comprises a plurality of first electrodes formed on a substrate, a plurality of second electrodes formed on the substrate below the plurality of first electrodes, and an organic luminescent layer formed between the plurality of first electrodes and the plurality of second electrodes, wherein the organic luminescent layer includes a red layer for emitting red light, a green layer for emitting green light, a blue layer for emitting blue light and a white layer for emitting white light.

The display device may further comprise a plurality of switching elements positioned on the substrate below the plurality of second electrodes. Each of the plurality of switching elements may include a gate electrode, a source electrode and a drain electrode, and each of the plurality of second electrodes may electrically contact the drain electrode via a pixel electrode. The display device may further comprise a plurality of insulating layers formed on the substrate below the plurality of second electrodes, and the substrate may include a transparent material.

A plurality of separating walls may be disposed between adjacent second electrodes of the plurality of second electrodes. The organic luminescent layer may be coated on the plurality of second electrodes and the plurality of separating walls. A sub-pixel may include at least one first electrode of the plurality of first electrodes, at least one second electrode of the plurality of second electrodes and one of the red, green, blue or white layers. An emitting region of each sub-pixel may be formed in a space between adjacent separating walls of the plurality of separating walls. The plurality of separating walls may cross peripheral portions of the plurality of second electrodes. The organic luminescent layer may be patterned using a shadow mask. Each of the red, green, blue and white layers may be one of a single layer structure or a multi layer structure. A plurality of sub-pixels may be arranged one of linearly, in a 2×2 lattice or in a 2×3 lattice. A protective layer may be formed on the plurality of first electrodes and connect the plurality of first electrodes to each other. The protective layer and the plurality of first electrodes may include a transparent material.

A light for displaying an image may be provided at a bottom or top portion of the display device. The plurality of first electrodes and the plurality of second electrodes may each be anodes or cathodes. A hole injection layer and a hole transportation layer may be formed between the plurality of first or second electrodes and the organic luminescent layer, and an electron transportation layer may be formed between the plurality of first or second electrodes and the organic luminescent layer.

Another display device, in accordance with an embodiment of the present invention, comprises a plurality of first electrodes formed on a substrate, a plurality of second electrodes formed on the substrate below the plurality of first electrodes, an organic luminescent layer formed between the plurality of first electrodes and the plurality of second electrodes, and a color filter layer formed on the substrate, wherein the color filter layer includes a red filter, a green filter, a blue filter and a white filter.

The color filter layer may be positioned below the plurality of second electrodes or above the plurality of first electrodes. The color filter layer may be positioned between two insulating layers of a plurality of insulating layers formed on the substrate below the plurality of second electrodes. The color filter layer may be patterned using a photolithography process. The white filter and the sibstrate may include a transparent material.

A sub-pixel may include at least one first electrode of the plurality of first electrodes, at least one second electrode of the plurality of second electrodes, a portion of the organic luminescent layer disposed between the at least one first electrode and the at least one second electrode, and one of the red, green, blue or white filters. An emitting region of each sub-pixel may be formed in a space between adjacent separating walls of a plurality of separating walls disposed between adjacent second electrodes of the plurality of second electrodes. The organic luminescent layer may be one of a single layer structure or a multi layer structure.

A protective layer may be formed on the plurality of first electrodes and the color filter layer may be formed on the protective layer.

Another display device, in accordance with an embodiment of the present invention, comprises a plurality of first electrodes formed on a substrate, a plurality of second electrodes formed on the substrate below the plurality of first electrodes, an organic luminescent layer formed between the plurality of first electrodes and the plurality of second electrodes, a color filter layer formed on the substrate under the plurality of second electrodes, wherein the color filter layer includes a red filter, a green filter, and a blue filter, and an insulating layer formed between the plurality of second electrodes and the color filter layer, wherein a portion of the insulating layer extends into the color filter layer.

The insulating layer may include an organic resin.

### BRIEF DESCRIPTION OF THE DRAWINGS

Preferred embodiments of the present invention can be understood in more detail from the following descriptions taken in conjunction with the accompanying drawings, in which:

FIGS. 1A to 1C are schematic views showing conventional structures for forming a color image in an OELD device;

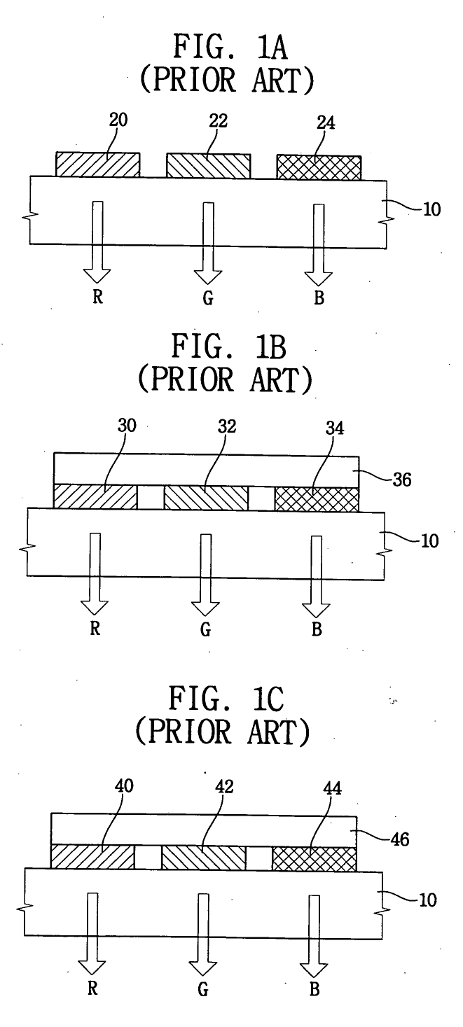

FIG. 2 is a structural view showing an OELD device according to an embodiment of the present invention;

FIGS. 3A to 3C are schematic views showing pixel arrangements for forming a color image in an OELD device according to an embodiment of the present invention;

FIG. 4 is a structural view showing an OELD device according to an embodiment of the present invention;

FIG. 5 is a structural view showing an OELD device according to an embodiment of the present invention; and

FIG. 6 is a structural view showing an OELD device according to an embodiment of the present invention.

### DETAILED DESCRIPTION OF THE PREFERRED EMBODIMENTS

Preferred embodiments of the present invention will be described below in more detail with reference to the accompanying drawings. This invention may, however, be embodied in different forms and should not be construed as limited to the embodiments set forth herein. Rather, these embodiments are provided so that this disclosure will be thorough and complete, and will fully convey the scope of the invention to those skilled in the art.

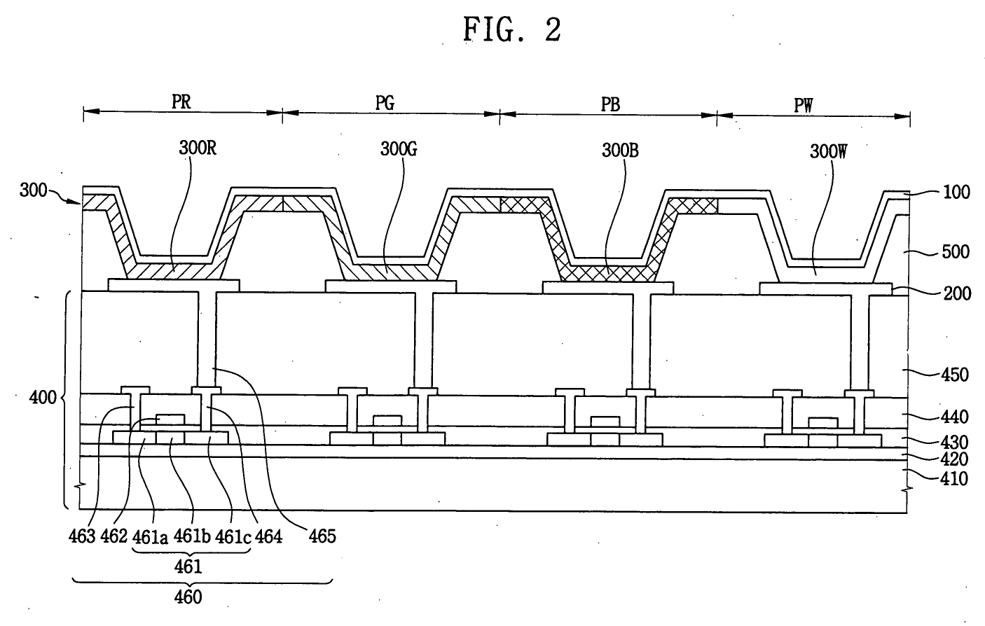

FIG. 2 is a structural view showing an OELD device according to an embodiment of the present invention. The OELD device shown in FIG. 2 forms a full color image using an independent RGB layer structure. The OELD device is a bottom generation type OELD device, wherein a light for displaying an image is generated at a bottom portion of the OELD device and is provided downwards.

Referring to FIG. 2, the OELD device includes a plurality of first electrodes 100 extending in a first direction, and a plurality of second electrodes 200 extending in a second direction perpendicular to the first direction to thereby form a plurality of sub-pixels with the first electrodes, and an organic luminescent layer 300 interposed between each of the first and second electrodes 100 and 200 corresponding to each of the sub-pixels, respectively. Therefore, each of the sub-pixels includes the first and second electrodes, and the organic luminescent layer interposed between the first and second electrodes. The organic luminescent layer 300 includes a red luminescent layer 300R for emitting red light, a green luminescent layer 300G for emitting green light, a blue luminescent layer 300B for emitting blue light, and a white luminescent layer 300W for emitting white light.

A support 400 is disposed below the second electrode 200 to support the second electrode 200. The support 400 includes a plurality of switching elements 460 corresponding to each of the second electrodes 200 for selectively transferring electrical signals to the second electrode 200. The present embodiment is based on an AMOLED device in which a thin film transistor (TFT) is used as a switching element. However, the present embodiment is not limited to an AMOLED device, and allows for other configurations that would be known to one of the ordinary skill in the art. The second electrode 200 of this embodiment functions as an anode, and the first electrode 100 functions as a cathode.

The support 400 includes a substrate 410, a plurality of insulating layers 420, 430, 440 and 450, and a plurality of TFTs 460 for transferring electrical signals to each of the second electrodes, respectively.

The substrate 410 is formed to be transparent so as to allow light generating at the bottom portion of the OELD device to pass through the substrate 410. The transparent substrate may include glass, quartz, glass ceramic, or crystallized glass for enduring high temperatures during the manufacturing process.

A substrate insulation layer 420 is coated on a whole surface of the substrate 410 for electrically isolating the substrate 410. The substrate insulation layer 420 may be effective when coated on a conductive substrate or a substrate including a plurality of moving ions. Therefore, the substrate insulation layer 420 may not necessarily be coated on a quartz substrate. The substrate insulation layer 420 may include silicon oxide, silicon nitride, or silicon oxidized nitride (SiOxNy, where x and y are integers that are greater than or equal to 1).

A plurality of active layers 461 of the TFT are positioned on an upper surface of the substrate insulation layer 420, each active layer corresponding to one of the plurality of the second electrodes 200, respectively. The active layer 461 includes a source portion 461a, a channel portion 461b, and a drain portion 461c. A gate insulation layer 430 is coated on the substrate 410 and the active layer 461, and a portion of the gate insulation layer 430 is removed leaving a thickness of the gate insulation layer 430 that is greater than the height of the active layer 461. Therefore, the gate insulation layer 430 planarizes the upper surface of the substrate 410 including a stepped portion formed by the active layer 461. A gate electrode 462 to which a selection signal is applied is positioned on a surface of the gate insulation layer 430 corresponding to the channel portion 461b of the active layer 461. A first interlayer insulation layer 440 is coated on the gate insulation layer 430 and the gate electrode 462. A portion of the first interlayer insulation layer 440 is removed leaving a thickness of the first interlayer insulation layer 440 that is greater than the height of the gate electrode 462. Therefore, the first interlayer insulation layer 440 planarizes the upper surface of the gate insulation layer 430 including a stepped portion formed by the gate electrode 462. A source electrode 463 and a drain electrode 464 are positioned on the planarized gate insulation layer 430 corresponding to the source portion 461a and drain portion 461c of the active layer 461, respectively. A data signal is applied to the source electrode 463, and the drain electrode 464 selectively makes electrical contact with the source electrode 463 according to the voltage of the selection signal applied to the gate electrode 462. A portion of the gate insulation layer 430 covering the source and drain portions 461a and 461c is opened, and the source and drain electrodes 463 and 464 make electrical contact with the source and drain portions 461a and 461c, respectively. Although the above embodiment discusses a single layer gate electrode, a multi-layer gate electrode such as a double layer gate electrode, a triple layer gate electrode or any other configuration known to one of ordinary skill in the art may also be utilized in place of or in conjunction with the single layer gate electrode.

A second interlayer insulation layer 450 is coated on the first interlayer insulation layer 440 and the source and drain electrodes 463 and 464, and a portion thereof removed resulting in a thickness of the second interlayer insulation layer 450 that is greater than the height of the source and drain electrodes 463 and 464. Therefore, the second interlayer insulation layer 450 planarizes the upper surface of the first interlayer insulation layer 440 including a stepped portion formed by the source and gate electrodes 463 and 464. The second electrode 200 is positioned on the surface of the planarized second interlayer insulation layer 450. A portion of the second interlayer insulation layer 450 covering the drain electrode 464 is opened to thereby form a contact hole. A conductive oxidized material is filled into the contact hole to form a pixel electrode 465. The second electrode 200 makes electrical contact with the drain electrode 464 through the pixel electrode 465. The second electrode 200 can be formed at the same time with the pixel electrode 465. The gate voltage applied to the gate electrode 462 controls the current passing to the second electrode 200.

A plurality of separating walls 500 are disposed to cover the space between adjacent second electrodes 200, so that an emitting region of each sub-pixel is defined in a space between the adjacent separating walls 500. The separating walls 500 are disposed so that the walls 500 cross peripheral portions of adjacent second electrodes 200. The organic luminescent layer 300 is coated on the second electrode 200 and the separating walls 500. In one embodiment, the organic luminescent layer 300 is patterned using a shadow mask such that each of the sub-pixels emits a color light among red, green, blue and white lights. Accordingly, the organic luminescent layer 300 includes the red luminescent layer 300R for emitting red light, the green luminescent layer 300G for emitting green light, the blue luminescent layer 300B for emitting blue light, and the white luminescent layer 300W for emitting white light. The sub-pixel corresponding to the red luminescent layer 300R is referred to as a red sub-pixel PR, the sub-pixel corresponding to the green luminescent layer 300G is referred to as a green sub-pixel PG, the sub-pixel corresponding to the blue luminescent layer 300B is referred to as a blue sub-pixel PB, and the sub-pixel corresponding to the white luminescent layer 300W is referred to as a white sub-pixel PW. Each of the luminescent layers 300R, 300G, 300B, and 300W may be a single layer structure or a multi-layer structure in which a plurality of organic thin layers are stacked for improving light efficiency. When a driving voltage is applied to the first and second electrodes 100 and 200, a plurality of electrons and holes are emitted into the organic luminescent layer 300 from the cathode and anode, respectively. The electrons and holes are recombined with each other in the organic luminescent layer 300 to thereby radiate light. In one embodiment, a hole injection layer and a hole transportation layer may be formed between the second electrode 200 and the organic luminescent layer 300, and an electron transportation layer may be formed between the first electrode 100 and the organic luminescent layer 300.

The first electrode 100 is formed on the organic luminescent layer 300, and protects the organic luminescent layer 300 from outer disturbances such as moisture. The first electrode 100 functions as a cathode in the present embodiment. In one embodiment, the first electrode 100 includes a metal that has a low ionization tendency and a low work function, and thus easily emits electrons therefrom. For example, the first electrode 100 may include magnesium (Mg), lithium (Li), calcium (Ca), or a combination thereof. A protective layer may be formed on the first electrode 100 so as to protect the first electrode 100 and may connect the first electrode on one of the sub-pixels with the first electrode on another sub-pixel.

According to an embodiment of the present invention, the white luminescent layer is formed in addition to the conventional red, blue, and green luminescent layers, thus the luminance and the light efficiency of the OELD device can be improved and power consumption can be reduced. Although a bottom generation type OELD device is shown, a top generation type OELD device, like that described in another embodiment may also be used.

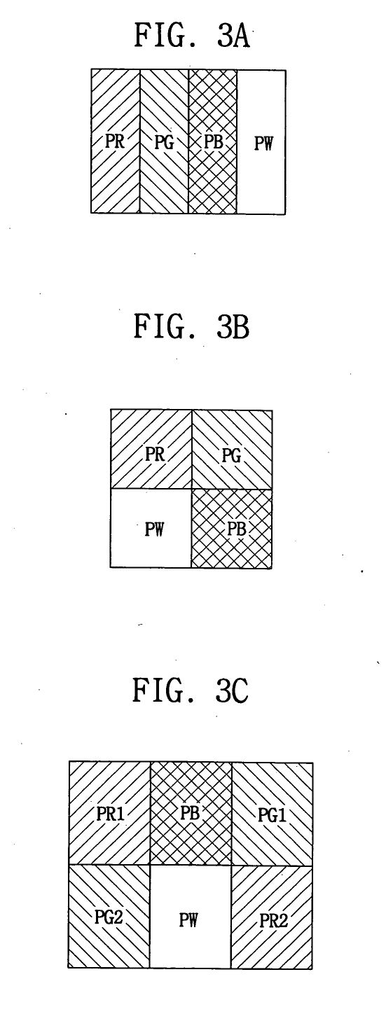

A pixel arrangement for the above 4-color system is hereinafter described with reference to FIGS. 3A to 3C.

Referring to FIG. 3A, the red, green, blue, and white sub-pixels PR, PG, PB, and PW are contiguously positioned in the first direction in the order named above to thereby be arranged linearly or in a stripe shape. Therefore, the OELD device including the pixel structure shown in FIG. 3A displays the full color image using the four-color system of the red, green, blue, and white sub-pixels PR, PG, PB, and PW. Sub-pixels having the same contact area, or contact areas different from each other may be utilized.

Referring to FIG. 3B, the red sub-pixel PR and the green sub-pixel PG are contiguously positioned in the first direction, and the red sub-pixel PR and the white sub-pixel PW are contiguously positioned in the second direction. In addition, the blue sub-pixel PB is point-symmetrical with respect to the red sub-pixel PR. Therefore, the pixel of the OELD device includes the red, green, blue, and white sub-pixels PR, PG, PB, and PW forming a 2×2 lattice.

Referring to FIG. 3C, each of the red and green sub-pixels, for example, is formed twice PR1, PR2, PG1, and PG2, and the each of the blue and white sub-pixels is formed once PB and PW. Therefore, the pixel of the OELD device includes the red, green, blue, and white sub-pixels PR, PG, PB, and PW forming a 2×3 lattice. In one embodiment, the red sub-pixels PR1 and PR2 are arranged spaced apart from each other by a predetermined distance and are adjacent to the green sub-pixels PG2 and PG1, respectively. Accordingly, the green sub-pixels PG1 and PG2 are also arranged spaced apart from each other by a predetermined distance and are adjacent to the red sub-pixels PR2 and PR1, respectively. Alternatively, the red or green sub-pixels may also be arranged adjacent to each other.

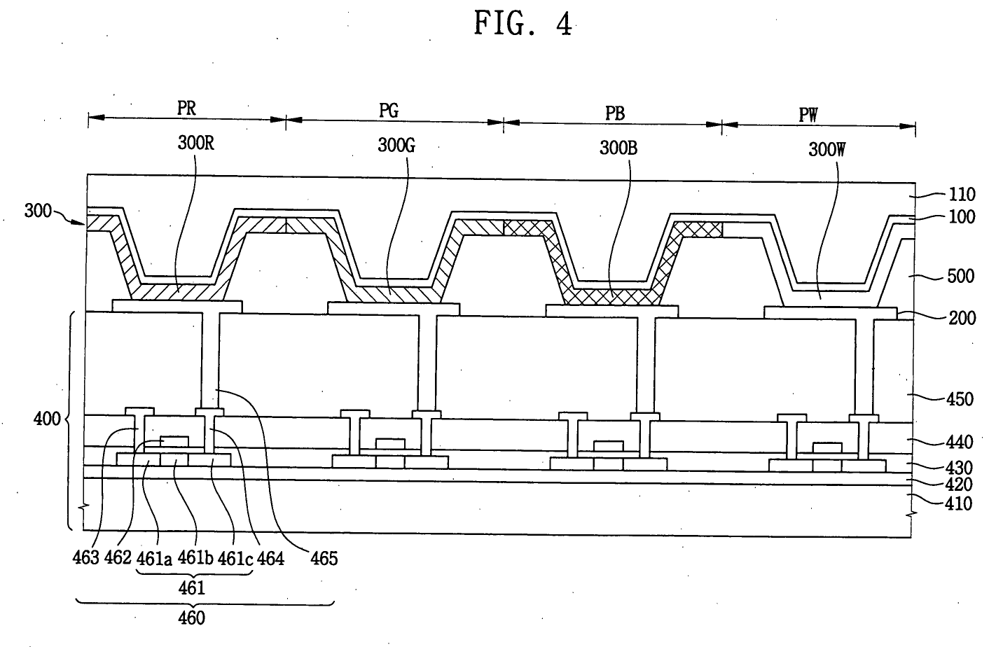

FIG. 4 is a structural view showing an OELD device according to another embodiment of the present invention. The OELD device according to this embodiment is identical to the OELD device according to the previous embodiment shown in FIG. 2, except that the OELD device of the present embodiment is a top generation type OELD device, wherein a light for displaying an image is generated at a top portion of the OELD device and provided upwards. In FIG. 4, the same reference numerals denote the same elements as in in FIG. 2, and detailed descriptions of the same elements will be omitted. As the OELD device of the present embodiment is the top generation type, the first and second electrodes function as the anode and cathode, respectively.

Referring to FIG. 4, the first electrode 100 is a transparent electrode including, for example, indium tin oxide (ITO) so as to allow the light generated in the organic luminescent layer 300 to pass upwards. A transparent sealing layer 110 may be formed on the first electrode 100 for protecting the first electrode 100 from outer disturbances such as foreign matters and moisture. As a cathode, the second electrode 200 includes a metal that has a low ionization tendency and a low work function, and thus easily emits electrons therefrom. For example, the second electrode 200 may include magnesium (Mg), lithium (Li), calcium (Ca), or a combination thereof. Unlike the bottom generation type OELD device, the hole injection layer and the hole transportation layer for improving a light generation efficiency may be formed between the first electrode 100 and the organic luminescent layer 300, and the electron transportation layer may be formed between the second electrode 200 and the organic luminescent layer 300.

The white luminescent layer 300W is formed in addition to the red, blue, and green luminescent layers 300R, 300B and 300G, thus the luminance and the light efficiency of the OELD device can be improved and power consumption reduced.

The organic luminescent layer 300 is independently coated on the electrodes and includes the red, blue, green and white luminescent layers 300R, 300G, 300B and 300W for individually emitting red, blue, green and white light. In accordance with the above-described embodiments, the red, green, blue and white material is deposited and patterned using a shadow mask.

Hereinafter, an OELD device having a color filter structure is described, wherein the color filter is formed through a conventional photolithography process without a shadow mask.

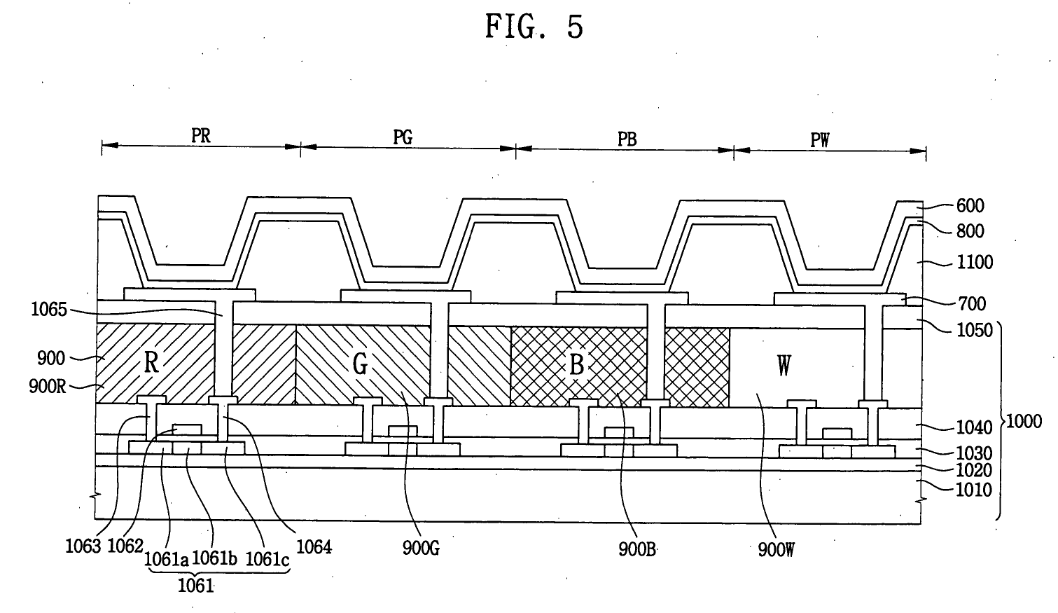

FIG. 5 is a structural view showing an OELD device according to another embodiment of the present invention. The OELD device of the embodiment shown in FIG. 5 forms a full color image with a color filter structure and is a bottom generation type OELD device, wherein a light for displaying an image is generated at a bottom portion thereof and provided downwards.

Referring to FIG. 5, the OELD device includes a plurality of first electrodes 600 extending in a first direction, a plurality of second electrodes 700 extending in a second direction perpendicular to the first direction to thereby form a plurality of sub-pixels, each including a first electrode 600, a second electrode 700 and an organic luminescent layer 800 interposed between the first electrode 600 and the second electrode 700, and a color filter layer 900 for individually emitting red, green, blue, and white light by filtering the light provided from the bottom portion of the OELD device.

A support 1000 is disposed below the second electrode 700 to support the second electrode 700. The support 1000 includes a plurality of switching elements 1060 corresponding to each of the second electrodes 700 for selectively transferring electrical signals to the second electrode 700. The present embodiment is based on an AMOLED device in which a thin film transistor (TFT) is used as the switching element. However, the embodiments of the present invention are not limited to an AMOLED device. The second electrode 700 functions as an anode and the first electrode 600 functions as a cathode.

The support 1000 includes a substrate 1010, a plurality of insulating layers 1020, 1030, 1040 and 1050, and a plurality of TFTs 1060 for transferring electrical signals to each of the second electrodes 700, respectively.

The substrate 1010 is formed to be transparent so as to allow the light generated at the bottom portion of the OELD device to pass through the substrate 1010. The transparent substrate 1010 may include glass, quartz, glass ceramic, or crystallized glass for enduring high temperatures during the manufacturing process.

A substrate insulation layer 1020 is coated on a surface of the substrate 1010 for electrically isolating the substrate 1010. As a result, the substrate insulation layer 1020 may be effective when coated on a conductive substrate or a substrate including a plurality of moving ions. Therefore, the substrate insulation layer 1020 may not necessarily be coated on a quartz substrate. The substrate insulation layer 1020 may include silicon oxide, silicon nitride, or silicon oxidized nitride (SiOxNy, where x and y are integers greater than or equal to 1).

A plurality of active layers 1061 of the TFT are positioned on an upper surface of the substrate insulation layer 1020, each active layer 1061 corresponding to one the plurality of the second electrodes 700, respectively. The active layer 1061 includes a source portion 1061a, a channel portion 1061b, and a drain portion 1061c. A gate insulation layer 1030 is coated on the substrate 1010 and the active layer 1061, and a portion of the gate insulation layer 1030 is removed leaving a thickness of the gate insulation layer 1030 that is greater than the height of the active layer 1061. Therefore, the gate insulation layer 1030 planarizes the upper surface of the substrate 1010 including a stepped portion formed by the active layer 1061. A gate electrode 1062 to which a selection signal is applied is positioned on a surface of the gate insulation layer 1030 corresponding to the channel portion 1061b of the active layer 1061. A first interlayer insulation layer 1040 is coated on the gate insulation layer 1030 and the gate electrode 1062, and a portion of the first interlayer insulation layer 1040 is removed leaving a thickness of the first interlayer insulation layer 1040 that is greater than the height of the gate electrode 1062. Therefore, the first interlayer insulation layer 1040 planarizes the upper surface of the gate insulation layer 1030 including a stepped portion formed by the gate electrode 1062. A source electrode 1063 and a drain electrode 1064 are positioned on the planarized gate insulation layer 1030 corresponding to the source portion 1061a and drain portion 1061c of the active layer 1061, respectively. A data signal is applied to the source electrode 1063, and the drain electrode 1064 selectively makes electrical contact with the source electrode 1063 according to the voltage of the selection signal applied to the gate electrode. A portion of the gate insulation layer 1030 covering the source and drain portions 1061a and 1061c is opened, whereby the source and drain electrodes 1063 and 1064 make electrical contact with the source and drain potions 1061a and 1061c, respectively. Although the above embodiment discusses a single layer gate electrode, a multi-layer gate electrode such as a double layer gate electrode, a triple layer gate electrode or any other configuration known to one of ordinary skill in the art may also be utilized in place of or in conjunction with the single layer gate electrode.

The color filter layer 900 is coated on the first interlayer insulation layer 1040. The color filter layer 900 is patterned through a photolithography process such that each of the sub-pixels emits one light color among red, green, blue, and white light. Accordingly, the color filter layer 900 includes a red filter 900R for emitting red light, a green filter 900G for emitting green light, a blue filter 900B for emitting blue light, and a white filter 900W for emitting white light. The sub-pixel corresponding to the red filter 900R is referred to as a red sub-pixel PR, the sub-pixel corresponding to the green filter 900G is referred to as a green sub-pixel PG, the sub-pixel corresponding to the blue filter 900B is referred to as a blue sub-pixel PB, and the sub-pixel corresponding to the white filter 900W is referred to as a white sub-pixel PW. In one embodiment, white light may be generated by emitting white light in the organic luminescent layer 800 and by forming the white filter 900W using a transparent material.

A second interlayer insulation layer 1050 is coated on the color filter layer 900, and planarizes the upper surface of the color filter layer 900. The second electrode 700 is positioned on the surface of the planarized second interlayer insulation layer 1050. In one embodiment, the second interlayer insulation layer 1050 may be an organic resin layer having good insulation and transparency characteristics, such as a polyimide layer, a polyamide layer, an acrylic layer and a benzo cyclobutene (BCB) layer. The organic resin layer preferably is flat and has a low dielectric constant. The white filter 900W may be omitted, and the second interlayer insulation layer 1050 may be extended in place of the white filter 900W.

A portion of the second interlayer insulation layer 1050 and a portion of the color filter layer 900 covering the drain electrode 1064 is opened to thereby form a contact hole. A conductive oxidized material is filled into the contact hole to form a pixel electrode 1065. The second electrode 700 makes electrical contact with the drain electrode 1064 through the pixel electrode 1065. The gate voltage applied to the gate electrode 1062 controls the current passing to the second electrode 700.

A plurality of separating walls 1100 are disposed to cover the space between the adjacent second electrodes 700, so that an emitting region of each sub-pixel is defined in a space between adjacent separating walls 1100. The separating walls 1100 are disposed so that the walls 1100 cross peripheral portions of adjacent second electrodes 700. The organic luminescent layer 800 is coated on the second electrodes 700 and the separating walls 1100. The organic luminescent layer 800 may be formed into a single layer structure or a multi-layer structure in which a plurality of organic thin layers are stacked for improving a light efficiency.

When a driving voltage is applied to the first and second electrodes 600 and 700, a plurality of electrons and holes is emitted into the organic luminescent layer 800 from the cathode and anode, respectively. The electrons and holes are recombined with each other in the organic luminescent layer 800 to thereby radiate light. In one embodiment, a hole injection layer and a hole transportation layer may be formed between the second electrode 700 and the organic luminescent layer 800, and an electron transportation layer may be formed between the first electrode 600 and the organic luminescent layer 800.

The first electrode 600 is formed on the organic luminescent layer 800, and protects the organic luminescent layer 800 from outer disturbances such as moisture. In one embodiment, the first electrode 600 includes a metal that has a low ionization tendency and a low work function, and thus easily emits electrons therefrom. For example, the first electrode 600 may include magnesium (Mg), lithium (Li), calcium (Ca), or a combination thereof. A protective layer may be formed on the first electrodes 600 so as to protect a first electrode 600 and connect the first electrode 600 on one of the sub-pixels with another first electrode 600 on the next sub-pixel.

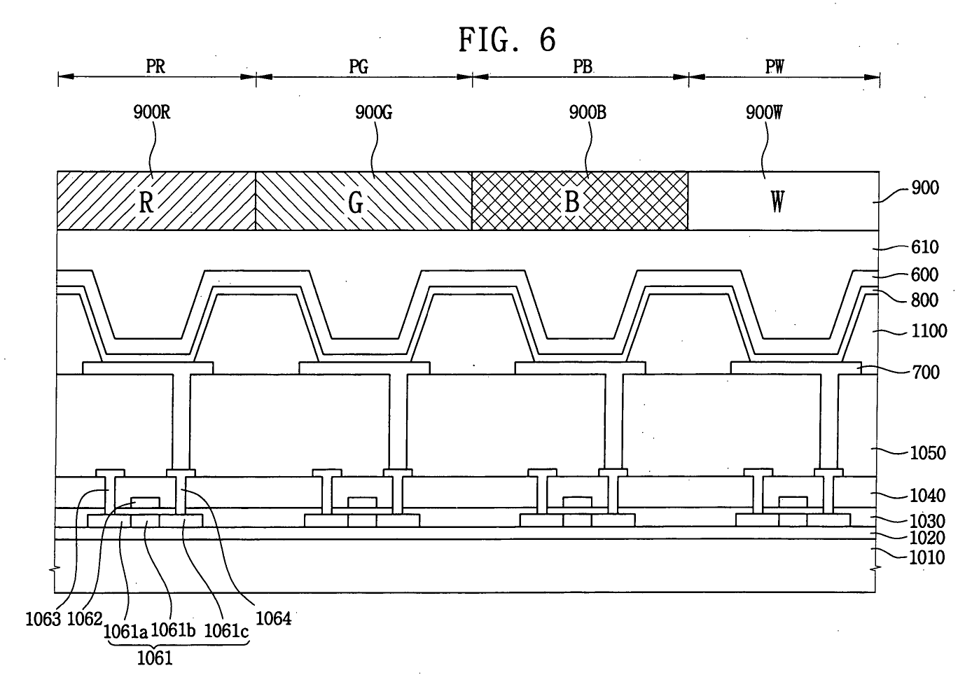

The embodiment described with reference to FIG. 5 includes the white filter in addition to the red, blue, and green filters, for improving luminance and light efficiency of the OELD device and reducing power consumption. This embodiment may be modified for a top generation type OELD device instead of a bottom generation type OELD device as described in the following with reference to FIG. 6.

FIG. 6 is a structural view showing an OELD device according to another embodiment of the present invention. The OELD device according to this embodiment is identical to the OELD device according to the embodiment described with reference to FIG. 5 except that a light for displaying an image is generated at the top portion of the OELD device and provided upwards, and the color filter layer is formed above the first electrode. In FIG. 6, the same reference numerals denote the same elements as in FIG. 5, and thus the detailed descriptions of the same elements will be omitted. As the OELD device of the embodiment referened in FIG. 6 is a top generation type OELD device, the first and second electrodes function as the anode and cathode, respectively.

Referring to FIG. 6, the first electrode 600 is a transparent electrode including, for example, indium tin oxide (ITO) so as to allow light generated in the organic luminescent layer 800 to pass upwards. A transparent sealing layer 610 may be coated on the first electrode 600 for protecting the first electrode 600 from outer disturbances such as foreign matter and moisture. As a cathode, the second electrode 700 includes a metal that has a low ionization tendency and a low work function, and thus easily emits electrons therefrom. For example, the second electrode 700 may include magnesium (Mg), lithium (Li), calcium (Ca), or a combination thereof. Unlike the bottom generation type OELD device, the hole injection layer and the hole transportation layer for improving light generation efficiency is formed between the first electrode 600 and the organic luminescent layer 800, and the electron transportation layer is formed between the second electrode 700 and the organic luminescent layer 800.

In one embodiment, the color filter layer 900 is coated on the transparent sealing layer 610. The color filter layer 900 is formed through a photolithography process such that each of the sub-pixels emits one light color among red, green, blue, and white light. Accordingly, the color filter layer 900 includes a red filter 900R for emitting red light, a green filter 900G for emitting green light, a blue filter 900B for emitting blue light, and a white filter 900W for emitting white light.

According to the OELD device described with reference to FIG. 6, the white filter is formed in addition to the red, blue, and green filters, for improving luminance and light efficiency of the OELD device and reducing power consumption. The top generation type OELD device has a higher resolution than that of the bottom generation type OELD device due to the positioning of the color filter on the sealing layer.

Hereinafter, light efficiency of a red, green, blue and white (RGBW) OELD device according to embodiments of the present invention will be described as compared with a conventional RGB OELD device.

The light efficiency of a conventional RGB display device may be expressed as the following.

$$E ( c d / A ) = \frac{L}{( \frac{I}{B} )} = \frac{{L}_{r} + {L}_{g} + {L}_{b}}{( \frac{{I}_{r} + {I}_{g} + {I}_{b}}{B} )} \qquad ( 1 )$$

In equation 1, the letter L is the luminance of the OELD device displaying a white color, the letter I is the total current of the OELD device displaying a white color, and the letter B is a total displaying area. In addition, the letters Lᵣ, L_{g} and L_{b} represent the luminance of the OELD device when the red sub-pixel emits the red color light, when the green sub-pixel emits the green color light, and when the blue sub-pixel emits the blue color light, respectively. The letters Iᵣ, I_{g} and I_{b} represent the current of the OELD device when the OELD device displays the red color, the green color and the blue color, respectively. The total displaying area B multiplied by an aperture ratio of the OELD device equals an effective displaying area.

Lᵣ, L_{g}, and L_{b} are expressed by the following equations.

$$\begin{matrix}{L}_{r} = L \cdot {X}_{r} = {φ}_{r} \cdot \frac{{I}_{r}}{B} & ( 2 ) \\ {L}_{g} = L \cdot {X}_{g} = {φ}_{g} \cdot \frac{{I}_{g}}{B} & ( 3 ) \\ {L}_{b} = L \cdot {X}_{b} = {φ}_{b} \cdot \frac{{I}_{b}}{B} & ( 4 )\end{matrix}$$

In the above equations, the letters Xᵣ, X_{g}, and X_{b} are color mixture ratios of the red, green, and blue color in an arbitrary color, respectively, and the letters φᵣ, φ_{g}, and φ_{b} represent luminance of the red, green, and blue lights per unit current, respectively. That is, the letters φᵣ, φ_{g}, and φ_{b} represent light efficiency of the red, green, and blue lights, respectively.

As a result, the light efficiency of the conventional RGB displaying device is determined in accordance with the following equation 5.

$$E ( c d / A ) = \frac{{φ}_{r} \cdot {I}_{r} + {φ}_{g} \cdot {I}_{g} + {φ}_{b} \cdot {I}_{b}}{{I}_{r} + {I}_{g} + {I}_{b}} = \frac{1}{( \frac{{X}_{r}}{{φ}_{r}} + \frac{{X}_{g}}{{φ}_{g}} + \frac{{X}_{b}}{{φ}_{b}} )} \qquad ( 5 )$$

Meanwhile, the light efficiency of the RGBW display device is expressed as the following equation 6.

$$E ( c d / A ) = \frac{L}{( \frac{I}{B} )} = \frac{{L}_{r} + {L}_{g} + {L}_{b} + {L}_{w}}{( \frac{{I}_{r} + {I}_{g} + {I}_{b} + {I}_{w}}{B} )} \qquad ( 6 )$$

In equation 6, the letter L is the luminance of the OELD device when all of the sub-pixels corresponding to the different colors emit light, and the letter L_{w} is the luminance of the OELD device when only the white sub-pixel emits the white light. The letter I is the current amount of the OELD device when all of the sub-pixels corresponding to the different colors emit light, and the letter I_{w} represents the current amount of the OELD device when the OELD device displays the white color. L_{w} is determined in accordance with equation 7, and Lᵣ is determined in accordance with equation 8.

$$\begin{matrix}{L}_{w} = \frac{L}{S} = \frac{a}{4} \cdot {I}_{w} = {φ}_{w} \cdot \frac{{I}_{w}}{B} & ( 7 ) \\ {L}_{r} = ( L - \frac{L}{S} ) \cdot {X}_{r} = {φ}_{r} \cdot \frac{{I}_{r}}{B} & ( 8 )\end{matrix}$$

In equation 8, the letter S is a scaling factor. L_{g}, and L_{b} are determined in a similar manner that of Lᵣ, whereby Xᵣ, φᵣ and Iᵣ in equation 8 are substituted by X_{g}, φ_{g} and I_{g} or X_{b}, φ_{b} and I_{b}, respectively.

As a result, the light efficiency of the RGBW OELD device is determined in accordance with the following equation 9.

$$E ( c d / A ) = \frac{{φ}_{r} \cdot {I}_{r} + {φ}_{g} \cdot {I}_{g} + {φ}_{b} \cdot {I}_{b} + {φ}_{b} {I}_{b}}{{I}_{r} + {I}_{g} + {I}_{b} + {I}_{w}} = \frac{S}{( S - 1 ) ( \frac{{X}_{r}}{{φ}_{r}} + \frac{{X}_{g}}{{φ}_{g}} + \frac{{X}_{b}}{{φ}_{b}} ) + \frac{1}{{φ}_{w}}} \qquad ( 9 )$$

The light efficiency may be represented for an OELD device of 64 gray levels.

Assuming that the coordinates of the red, green, and blue colors are (0.63, 0.35), (0.28, 0.67), and (0.15, 0.15) according to the Commission Internationale de I'Eclairage (CIE) color coordinate system and the color reproducibility of the conventional RGB independent type OELD device is about 71%, then the color mixture ratios Xᵣ, X_{g}, and X_{b} of the red, green, and blue color for forming the white color having the CIE coordinates (0.29, 0.32) are about 0.25, 0.5, and 0.25, respectively. The luminance of the red, green, and blue lights per unit current φᵣ, φ_{g}, and φ_{b} are about 3.0, 7.0, and 6.0, respectively. Therefore, the light efficiency of the conventional RGB independent type OELD device is about 5.1 (cd/A).

Meanwhile, assuming that the coordinates of the red, green, and blue colors are (0.63, 0.35), (0.27, 0.60), and (0.15, 0.19) according to the CIE color coordinate system and the color reproducibility of the conventional RGB color filter type OELD device is about 56%, then the color mixture ratios Xᵣ, X_{g}, and X_{b} of the red, green, and blue color for forming the white color having the CIE coordinates (0.29, 0.32) are about 0.26, 0.42, and 0.32, respectively. The luminance of the red, green, and blue lights per unit current φᵣ, φ_{g}, and φ_{b} are about 3.0, 7.0, and 6.0, respectively. Therefore, the light efficiency of the conventional RGB color filter type OELD device is about 3.7 (cd/A).

The above sampling results on the RGB independent type and color filter type OELD device indicate that the light efficiency of the color filter type OELD device is better than that of the RGB independent type OELD device by as much as about 73%.

With respect to the embodiments described in connection with FIGS. 5 and 6, assuming that the coordinates of the red, green, and blue colors are (0.63, 0.35), (0.27, 0.60), and (0.15, 0.19) according to the CIE color coordinate system, then the color mixture ratios Xᵣ, X_{g}, and X_{b} of the red, green, and blue color for forming the white color having the CIE coordinates (0.29, 0.32) are about 0.26, 0.42, and 0.32, respectively. The luminance of the red, green, blue, and white lights per unit current φᵣ, φ_{g}, φ_{b}, and φ_{w} are about 1.8, 5.7, 5.7, and 15 respectively. Therefore, the light efficiency of the OELD device with respect to the embodiments described in connection with FIGS. 5 and 6, is about 5.9 (cd/A) when the scaling factor S is 2.

As a result, when the OELD device forms the full color image using the color filter structure, the light efficiency of the RGBW OELD device is as much as 159% better than the light efficiency of the conventional RGB OELD device. Furthermore, the light efficiency of the color filter type RGBW OELD device is better than that of the independent RGB layer type RGB OELD device by as much as 116%.

The color filter type OELD device according to the embodiments described in connection with FIGS. 5 and 6 can be manufactured without the shadow mask, so that a marginal region for the shadow region is not needed, thereby reducing the number of wires. As a result, the aperture ratio is not deteriorated even though the pixel area may be reduced due to additional TFTs required for corresponding to the added white sub-pixels of an RGBW OELD device.

According to embodiments of the present invention, a white sub-pixel is formed in addition to red, blue, and green sub-pixels, for improved luminance over a conventional RGB type device.

Although the illustrative embodiments have been described herein with reference to the accompanying drawings, it is to be understood that the present invention is not limited to those precise embodiments, and that various other changes and modifications may be affected therein by one of ordinary skill in the related art without departing from the scope or spirit of the invention. All such changes and modifications are intended to be included within the scope of the invention as defined by the appended claims.

What is claimed is:

1. A display device, comprising:
a plurality of first electrodes formed on a substrate;
a plurality of second electrodes formed on the substrate below the plurality of first electrodes; and
an organic luminescent layer formed between the plurality of first electrodes and the plurality of second electrodes, wherein the organic luminescent layer includes a red layer for emitting red light, a green layer for emitting green light, a blue layer for emitting blue light and a white layer for emitting white light.

2. The display device as recited in claim 1, further comprising a plurality of switching elements positioned on the substrate below the plurality of second electrodes.

3. The display device as recited in claim 2, wherein each of the plurality of switching elements includes a gate electrode, a source electrode and a drain electrode.

4. The display device as recited in claim 3, wherein each of the plurality of second electrodes electrically contacts the drain electrode via a pixel electrode.

5. The display device as recited in claim 1, further comprising a plurality of insulating layers formed on the substrate below the plurality of second electrodes.

6. The display device as recited in claim 1, wherein the substrate includes a transparent material.

7. The display device as recited in claim 1, further comprising a plurality of separating walls disposed between adjacent second electrodes of the plurality of second electrodes.

8. The display device as recited in claim 7, wherein the organic luminescent layer is coated on the plurality of second electrodes and the plurality of separating walls.

9. The display device as recited in claim 7, wherein:
a sub-pixel includes at least one first electrode of the plurality of first electrodes, at least one second electrode of the plurality of second electrodes and one of the red, green, blue or white layers; and
an emitting region of each sub-pixel is formed in a space between adjacent separating walls of the plurality of separating walls.

10. The display device as recited in claim 7, wherein the plurality of separating walls cross peripheral portions of the plurality of second electrodes.

11. The display device as recited in claim 1, wherein the organic luminescent layer is patterned using a shadow mask.

12. The display device as recited in claim 1, wherein each of the red, green, blue and white layers is one of a single layer structure or a multi layer structure.

13. The display device as recited in claim 1, wherein:
a sub-pixel includes at least one first electrode of the plurality of first electrodes, at least one second electrode of the plurality of second electrodes and one of the red, green, blue or white layers; and
a plurality of sub-pixels are arranged one of linearly, in a 2×2 lattice or in a 2×3 lattice.

14. The display device as recited in claim 1, further comprising a protective layer formed on the plurality of first electrodes.

15. The display device as recited in claim 14, wherein the protective layer connects the plurality of first electrodes to each other.

16. The display device as recited in claim 14, wherein the protective layer includes a transparent material.

17. The display device as recited in claim 1, wherein the plurality of first electrodes include a transparent material.

18. The display device as recited in claim 1, wherein a light for displaying an image is provided at a bottom portion of the display device.

19. The display device as recited in claim 18, wherein the plurality of first electrodes are cathodes and the plurality of second electrodes are anodes.

20. The display device as recited in claim 18, further comprising:
a hole injection layer and a hole transportation layer formed between the plurality of second electrodes and the organic luminescent layer; and
an electron transportation layer formed between the plurality of first electrodes and the organic luminescent layer.

21. The display device as recited in claim 1, wherein a light for displaying an image is provided at a top portion of the display device.

22. The display device as recited in claim 21, wherein the plurality of first electrodes are anodes and the plurality of second electrodes are cathodes.

23. The display device as recited in claim 21, further comprising:
a hole injection layer and a hole transportation layer formed between the plurality of first electrodes and the organic luminescent layer; and
an electron transportation layer formed between the plurality of second electroded and the organic luminescent layer.

24. A display device, comprising:
a plurality of first electrodes formed on a substrate;
a plurality of second electrodes formed on the substrate below the plurality of first electrodes;
an organic luminescent layer formed between the plurality of first electrodes and the plurality of second electrodes; and
a color filter layer formed on the substrate, wherein the color filter layer includes a red filter, a green filter, a blue filter and a white filter.

25. The display device as recited in claim 24, wherein the color filter layer is positioned one of below the plurality of second electrodes or above the plurality of first electrodes.

26. The display device as recited in claim 24, further comprising a plurality of switching elements positioned on the substrate below the plurality of second electrodes.

27. The display device as recited in claim 26, wherein each of the plurality of switching elements includes a gate electrode, a source electrode and a drain electrode.

28. The display device as recited in claim 27, wherein each of the plurality of second electrodes electrically contacts the drain electrode via a pixel electrode.

29. The display device as recited in claim 24, further comprising a plurality of insulating layers formed on the substrate below the plurality of second electrodes.

30. The display device as recited in claim 29, wherein the color filter layer is positioned between two insulating layers of the plurality of insulating layers.

31. The display device as recited in claim 24, wherein the color filter layer is patterned using a photolithography process.

32. The display device as recited in claim 24, wherein the white filter includes a transparent material.

33. The display device as recited in claim 24, wherein the substrate includes a transparent material.

34. The display device as recited in claim 24, further comprising a plurality of separating walls disposed between adjacent second electrodes of the plurality of second electrodes.

35. The display device as recited in claim 34, wherein the organic luminescent layer is coated on the plurality of second electrodes and the plurality of separating walls.

36. The display device as recited in claim 34, wherein:
a sub-pixel includes at least one first electrode of the plurality of first electrodes, at least one second electrode of the plurality of second electrodes, a portion of the organic luminescent layer disposed between the at least one first electrode and the at least one second electrode, and one of the red, green, blue or white filters; and
an emitting region of each sub-pixel is formed in a space between adjacent separating walls of the plurality of separating walls.

37. The display device as recited in claim 34, wherein the plurality of separating walls cross peripheral portions of the plurality of second electrodes.

38. The display device as recited in claim 24, wherein the organic luminescent layer is one of a single layer structure or a multi layer structure.

39. The display device as recited in claim 24, further comprising a protective layer formed on the plurality of first electrodes.

40. The display device as recited in claim 39, wherein the protective layer connects the plurality of first electrodes to each other.

41. The display device as recited in claim 39, wherein the protective layer includes a transparent material.

42. The display device as recited in claim 41, wherein the color filter layer is formed on the protective layer.

43. The display device as recited in claim 24, wherein the plurality of first electrodes include a transparent material.

44. The display device as recited in claim 24, wherein a light for displaying an image is provided at a bottom portion of the display device.

45. The display device as recited in claim 44, wherein the plurality of first electrode are cathodes and the plurality of second electrodes are anodes.

46. The display device as recited in claim 44, further comprising:
a hole injection layer and a hole transportation layer formed between the plurality of second electrodes and the organic luminescent layer; and
an electron transportation layer formed between the plurality of first electrodes and the organic luminescent layer.

47. The display device as recited in claim 24, wherein a light for displaying an image is provided at a top portion of the display device.

48. The display device as recited in claim 47, wherein the plurality of first electrodes are anodes and the plurality of second electrodes are cathodes.

49. The display device as recited in claim 47, further comprising:
a hole injection layer and a hole transportation layer formed between the plurality of first electrodes and the organic luminescent layer; and
an electron transportation layer formed between the plurality of second electroded and the organic luminescent layer.

50. A display device, comprising:
a plurality of first electrodes formed on a substrate;
a plurality of second electrodes formed on the substrate below the plurality of first electrodes;
an organic luminescent layer formed between the plurality of first electrodes and the plurality of second electrodes;
a color filter layer formed on the substrate under the plurality of second electrodes, wherein the color filter layer includes a red filter, a green filter, and a blue filter; and
an insulating layer formed between the plurality of second electrodes and the color filter layer, wherein a portion of the insulating layer extends into the color filter layer.

51. The display device as recited in claim 50, wherein the insulating layer includes an organic resin.
